(19) United States
(12) Patent Application Publication
(10) Pub. No.: US 2010/0011565 A1
(43) Pub. Date: Jan. 21, 2010

(54) METHODS OF FORMING A LENS SHEET FOR A PHOTOVOLTAIC SOLAR CELL SYSTEM

(75) Inventors: Peter ZAWADZKI, Clinton, NJ (US); Gary Hering, Belle Bead, NJ (US); Mikhail Kats, Rockaway, NJ (US); Jim Sherman, Hillsborough, NJ (US); Alan Gorentz, Albuquerque, NM (US)

Correspondence Address: EMCORE CORPORATION, 1600 EUBANK BLVD, S.E., ALBUQUERQUE, NM, 87123, US

(73) Assignee: Emcore Corporation, Albuquerque, NM (US)

(21) Appl. No.: 12/177,031

(22) Filed: Jul. 21, 2008

(51) Int. Cl. H01L 31/18; B23K 26/20

(52) U.S. Cl. 29/592.1; 29/890.033; 29/428; 219/121.64

(57) ABSTRACT

The present application is directed to methods of forming an integral lens sheet for use with a photovoltaic solar cell subassembly. The integral lens sheet is constructed from a parquet member and one or more individual lenses. One embodiment of a method may include positioning an individual lens over each of the apertures in the parquet member. The size of the lenses may provide for peripheral sections of the lenses to overlap the parquet member. Each of the lenses may be welded to the parquet member by directing a laser beam through the peripheral sections and onto the parquet member. The laser beam may form a laser weld between the parquet member and an underside of the individual lenses.

### REFERENCE TO RELATED APPLICATIONS

This application is related to co-pending U.S. patent application Ser. No. 12/131,556 filed Jun. 2, 2008 entitled Terrestrial Solar Array Including a Rigid Support Frame. The application is also related to U.S. Pat. No. 7,381,886 entitled Terrestrial Solar Array and divisional application Ser. No. 12/024,489. Each of these applications and patent were filed by the assignee of the present application.

### Background

A photovoltaic solar cell subassembly converts sunlight into electrical energy. The subassembly generally includes lenses that are each aligned to concentrate the sunlight onto solar cell receivers. The lenses and solar cell receivers are normally mounted within a frame with the lenses being spaced away from the solar cell receivers. The number of lenses and solar cell receivers may vary depending upon the desired electrical output. Further, the lenses and solar cell receivers may be mounted on a support structure that moves such that the lenses remain facing towards the sun during the progression of the day.

Multiple lenses may be attached to a single base sheet. The base sheet may facilitate placement of the lenses relative to each other, and may also position each lens relative to a different solar cell receiver. Accurate alignment is needed between the lenses and their respective solar cell receivers to ensure the sunlight is accurately concentrated on the solar cell receivers to optimize the electrical output. Misalignment between the lenses and the solar cell receivers may result in the overall electrical output of the photovoltaic solar cell subassembly being less than expected.

Methods of attaching the lenses to the base sheet should provide for accurate placement of the lenses relative to each other, and accurate alignment relative to their respective solar cell receiver. The methods should also prevent damage to the lenses during attachment to the base sheet. Damage such as but not limited to scratching and cracking may occur as the lenses are placed onto and attached to the base sheet. Damage to the lenses may result in less sunlight being concentrated on the solar cell receivers which may negatively affect the overall electrical output of the subassembly.

The lenses and base sheet are often positioned on an exterior, top surface of the subassembly to optimize the amount of sunlight that may be captured. This positioning often results in the lenses and base sheet forming a protective covering for the more fragile solar cell receivers and associated hardware. The lenses and base sheet should be able to withstand extreme weather conditions that include excessive heat and frigid cold which may occur due to the frequent placement of these subassemblies in desert-like environments that provide a maximum amount of available sunlight. Further, the lenses and base sheet should also provide protection from rain, snow, hail, and the like that may also be encountered.

### SUMMARY

The present application is directed to methods of forming integral lens sheets for use with a photovoltaic solar cell subassembly. The integral lens sheets may be constructed from a parquet member and one or more individual lenses. One embodiment of a method may include positioning an individual lens over each of the apertures in the parquet member. The size of the lenses may provide for peripheral sections of the lenses to overlap the parquet member. Each of the lenses may be welded to the parquet member by directing a laser beam through the peripheral sections and onto the parquet member. The laser beam may form a laser weld between the parquet member and an underside of the individual lenses.

The various aspects of the various embodiments may be used alone or in any combination, as is desired.

### BRIEF DESCRIPTION OF THE DRAWINGS

FIG. 1 is an exploded view of lenses, a parquet member, and an alignment fixture according to one embodiment.

FIG. 2 is a top view of an alignment fixture according to one embodiment and a section view cut along line A-A.

FIG. 3 is a top view of an alignment section of an alignment fixture according to one embodiment.

FIG. 4 is an exploded perspective view of an alignment section of an alignment fixture and an alignment member according to one embodiment.

FIG. 5 is a top view of an alignment member according to one embodiment and a section view cut along line B-B.

FIG. 6 is a section view of an alignment member attached to an alignment fixture according to one embodiment.

FIG. 7 is a section view of a lens according to one embodiment.

FIG. 8 is a section view of an alignment fixture and alignment member aligning a lens relative to an aperture in a parquet member according to one embodiment.

FIG. 9 is a cut-away perspective view of an integral lens sheet in a photovoltaic solar cell subassembly according to one embodiment.

FIG. 10 is a perspective view of a laser welding station for laser welding lenses to a parquet member according to one embodiment.

### DETAILED DESCRIPTION

The present application is directed to methods of forming an integral lens sheet for use with a concentrating photovoltaic solar cell subassembly. The methods include attaching one or more lenses to a parquet member. An alignment fixture may be used during the process for accurately placing the lenses onto the parquet member, and also to accurately place multiple lenses relative to teach other. The alignment fixture may also protect the lenses during the attachment to prevent scratching or other damage to the lenses that could negatively affect the electrical output of the photovoltaic solar cell subassembly.

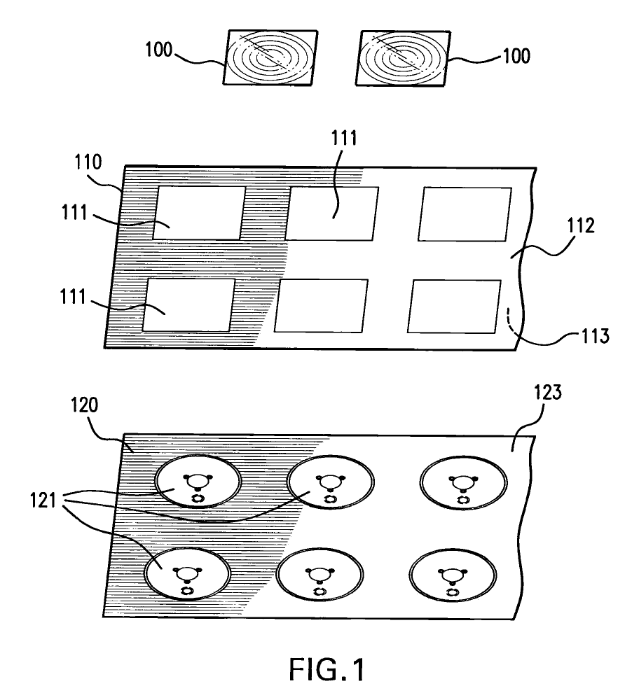

FIG. 1 illustrates several elements used in the methods of making an integral lens sheet. The lenses 100 and parquet member 110 are combined together to form the integral lens sheet. The parquet member 110 includes apertures 111 that are each sized to receive one of the lenses 100. An alignment fixture 120 supports and positions the parquet member 110 during attachment of the lenses 100. Alignment fixture 120 includes alignment sections 121 that each correspond to a different aperture 111 in the parquet member 110. The alignment sections 121 position the lenses 100 during the attachment to the parquet member 110.

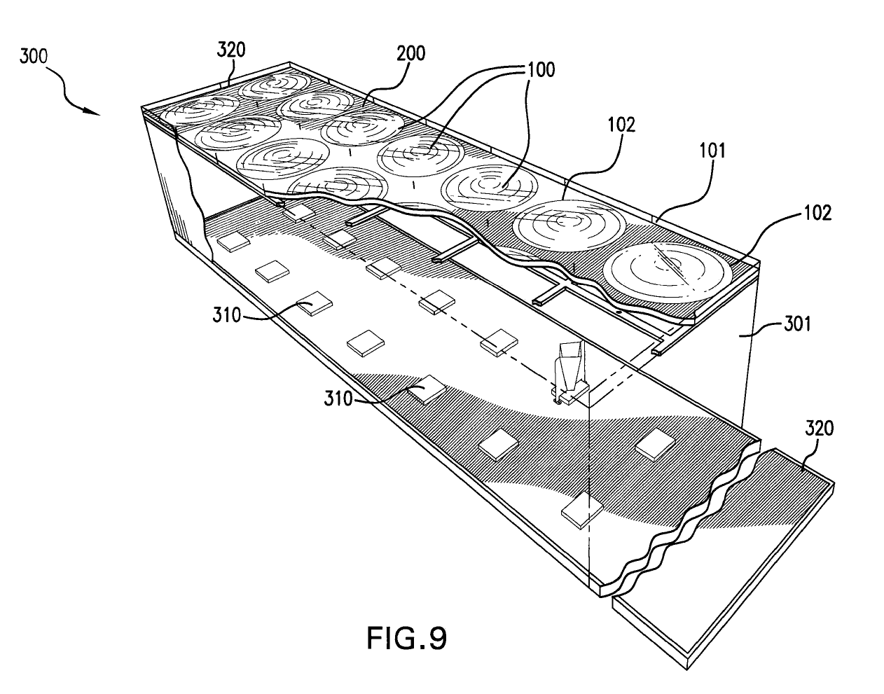

FIG. 9 illustrates an integral lens sheet 200 that is part of a photovoltaic solar cell subassembly 300. The integral lens sheet 200 includes lenses 100 that are attached to the parquet member 110. The integral lens sheet 200 is attached to a frame 300 with each of the lenses 100 positioned over and aligned with a different solar cell receiver 310 that is mounted to a support 320 and positioned below the lens sheet 200.

Lenses 100 concentrate sunlight onto a solar cell receiver 310 positioned below on the support 320 of the photovoltaic solar cell subassembly 300. The lenses 100 may be Fresnel lenses, or may be conventional spherical lenses. An advantage of Fresnel lenses is they require less material compared to a conventional spherical lens. As best illustrated in FIGS. 7 and 8, the Fresnel lens 100 includes a set of concentric annular sections referred to as Fresnel zones that give the lens a second surface 104 an overall jagged construction that provides a reduction in thickness and thus material over a convention spherical lens. The reduction in thickness may also provide a reduction in the overall weight of the lens 100.

As illustrated in the Fresnel lens embodiments of FIGS. 7 and 8, each lens 100 includes a substantially smooth first surface 103, and jagged second surface 104. The lens 100 is positioned on the parquet member 110 with the first surface 103 facing away from the parquet member 110, and the second surface 104 facing towards the parquet member 110 with a peripheral section 107 contacting the parquet member 110. A curved central section 105 is positioned on the second surface 104. Further, second surface 104 includes one or more extensions 106. Extensions 106 extend outward and contact the parquet member 110. In one embodiment, the extensions 106 contact against an edge of the aperture 111 to align the lens 100 relative to the parquet member 110. The amount the extensions 106 extend outward from the lens 100, and the length of the extensions 106 may vary. In one specific embodiment, four extensions 106 extend outward with each contacting a different surface of a rectangular aperture 111. In another embodiment, the extension 106 is continuous and forms an enclosed shape that contacts against an entire edge of a correspondingly shaped aperture 111 (e.g., a rectangular shape that contacts against each surface of a rectangular aperture 111). The second surface 104 may also include a substantially smooth peripheral section 107 that contacts against the parquet member 110 as illustrated in FIG. 8.

The embodiment of FIG. 1 includes each of the lenses 100 having a rectangular shape. In one embodiment, each lens 100 is 9 inches by 9 inches. Each of the lenses 100 that form the integral lens sheet 200 may include the same shape and size, or the lenses 100 may include different shapes and/or sizes. Materials the lenses 100 may be made from include but are not limited to acrylic, plastic, and glass.

The parquet member 110 positions the lenses 100 and includes a first surface 112 that contacts the lenses 100 and an opposite second surface 113 that faces away from the lenses 100. Apertures 111 extend through the parquet member 110 and each is sized to receive a lens 100. The apertures 111 may include a variety of shapes and sizes, and each of the apertures 111 may include the same or different shapes and/or sizes. The apertures 111 are smaller than the lenses 100 such that the peripheral section 107 of the lenses 100 contact against the first surface 112 of the parquet member 110. The parquet member 110 may be constructed from various materials including but not limited to plastic, acrylic, and aluminum. The parquet member 110 may include various configurations and numbers of apertures 111. In one specific embodiment, the parquet member 110 includes two rows of seven apertures 111.

The section of the first surface 112 that surrounds the apertures may be constructed to absorb a laser beam that is applied to the parquet member 110 during laser welding as will be explained in detail below. One type of construction includes these sections of the first surface 112 including a darkened color, such as black, dark brown, and the like that prevents transmission of the laser beam. The sections may also include a near infrared (NIR) absorbing dye on the first surface 112 either instead of or in combination with the darkened color. The laser-absorbing section of the first surface 112 may extend across the entire first surface 112, or may extend across limited sections of the first surface 112, such as around each of the apertures where the peripheral sections 107 of the lenses 100 overlap the first surface 112. In one embodiment, the entire first surface 112 is laser-absorbing.

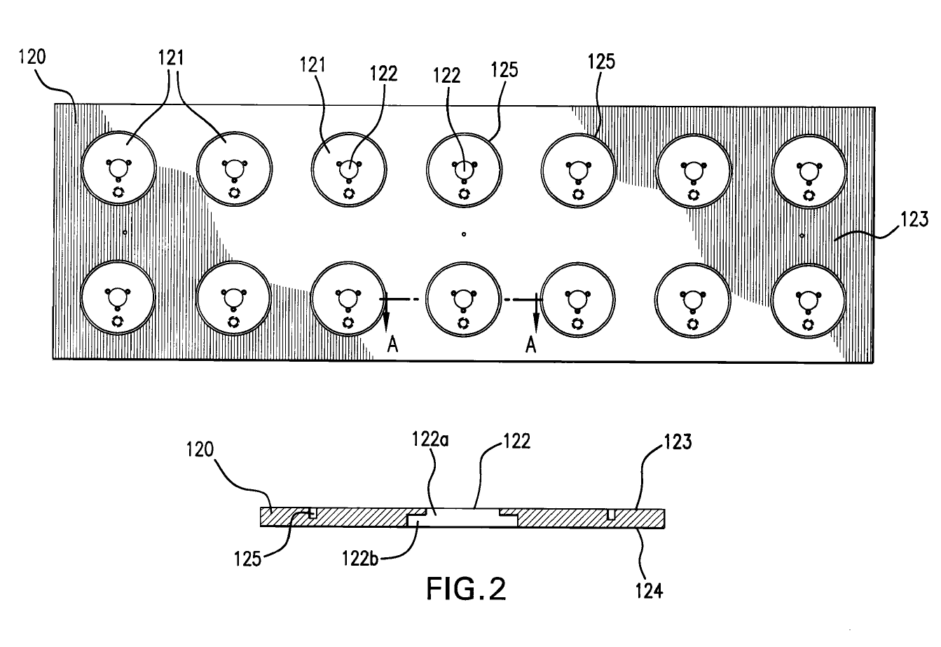

The alignment fixture 120 is used during attachment of the lenses 100 to the parquet member 110 and is removed prior to the integral lens sheet 200 being attached to the frame 301 of the photovoltaic solar cell subassembly 300. The alignment fixture 120 includes a first surface 123 that faces towards the parquet member 110 and a second surface 124 that faces away from the second surface 124. The alignment fixture 120 may include the same or different shape and/or size as the parquet member 110. The embodiment of FIG. 2 includes the alignment fixture 120 with the same shape and size to correspond to a parquet member 110 that includes two rows of seven apertures 111.

Alignment sections 121 are positioned on the alignment fixture 120 and align with the apertures 111 in the parquet member 110. In the embodiment of FIG. 2, each alignment section 121 includes the same shape and size, however, other embodiments may include one or more of the alignment sections 121 including different shapes and/or sizes.

As illustrated in FIGS. 2, 3, and 4, the alignment section 121 includes an aperture 122 and a groove 125 extends into the first surface 123 and may extend around the aperture 122. The aperture 122 and groove 125 may include various shapes, including circular as illustrated. As illustrated in FIG. 2, aperture 122 includes a first section 122a at the first surface 123 that includes a smaller diameter than a second section 122b at the second surface 124. This configuration is to receive an alignment member 130 as will be explained in detail below. The groove 125 is configured to receive an o-ring to form a vacuum retention seal as will be explained below.

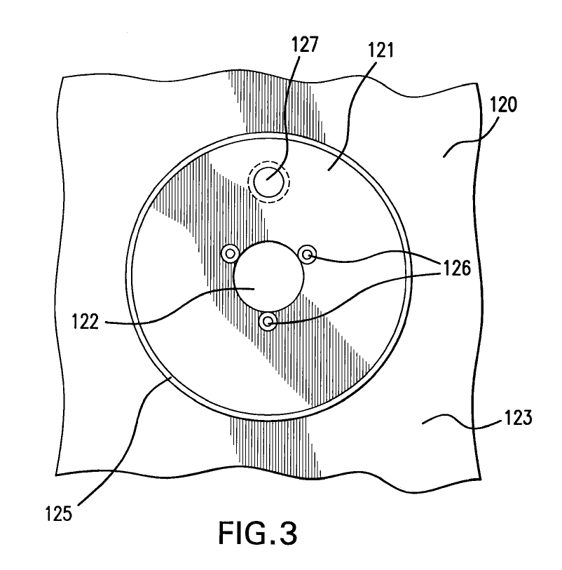

One or more receptacles 126 are positioned adjacent to the aperture 122 to receive fasteners 190 to attach the alignment member 130. The receptacles 126 may extend completely or only partially through the alignment fixture 120. The receptacles 126 may include a tapered shape with a larger diameter at the first surface 123 as illustrated in FIG. 3 for heads of the fasteners 190 to be flush with or slightly below the first surface 123.

A vacuum aperture 127 is positioned in proximity to the aperture 122. This allows for vacuum pressure to be applied to the lens 100 during attachment to the parquet member 110 as will be explained in detail below.

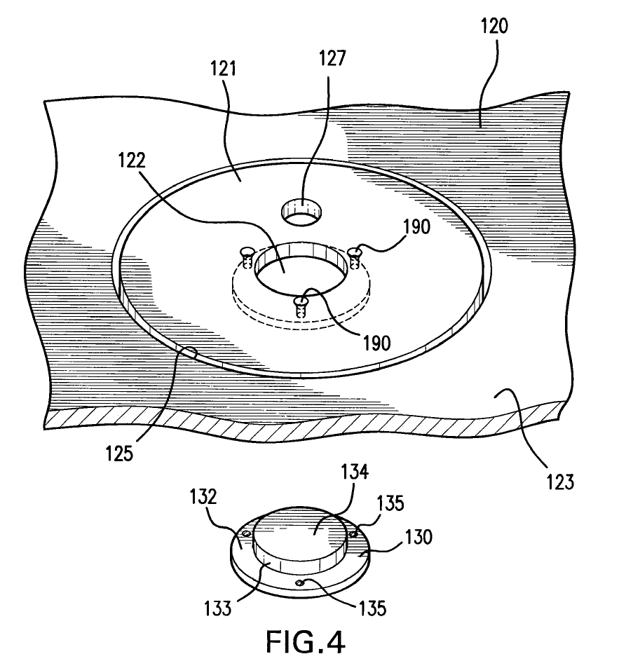

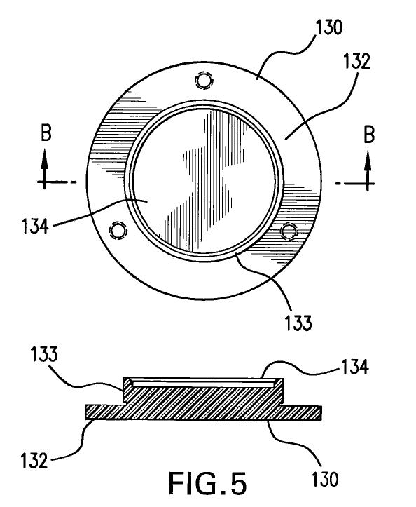

An alignment member 130 is attached to each of the alignment sections 121 in the alignment fixture 120 to align the lens 100 with the parquet member 110. As illustrated in FIGS. 4, 5, and 6, the alignment member 130 includes a flange 132 and an outwardly-extending neck 133. The flange 132 is sized to fit within the second section 122b of the aperture 122, and the neck 133 to fit within the first section 122a. The neck 133 may further include a length to extend upward above the first surface 123 of the alignment fixture 120. Receptacles 135 may be positioned on the flange 132 and align with receptacles 126 on the alignment fixture 120 to receive the fasteners 190 to attach the alignment member 130 to the alignment fixture 120. The alignment member 130 may also be attached to the alignment fixture 120 by an adhesive. A contact member 134 extends across the neck 133 and contacts against the central section 105 of the lens 100. The contact member 134 is constructed of a softer material than the lens 100 to prevent the lens 100 from being damaged during attachment to the parquet member 110. Materials for the contact member 134 include but are not limited to DELRIN, acetylcopolymer, TEFLON, and plastic.

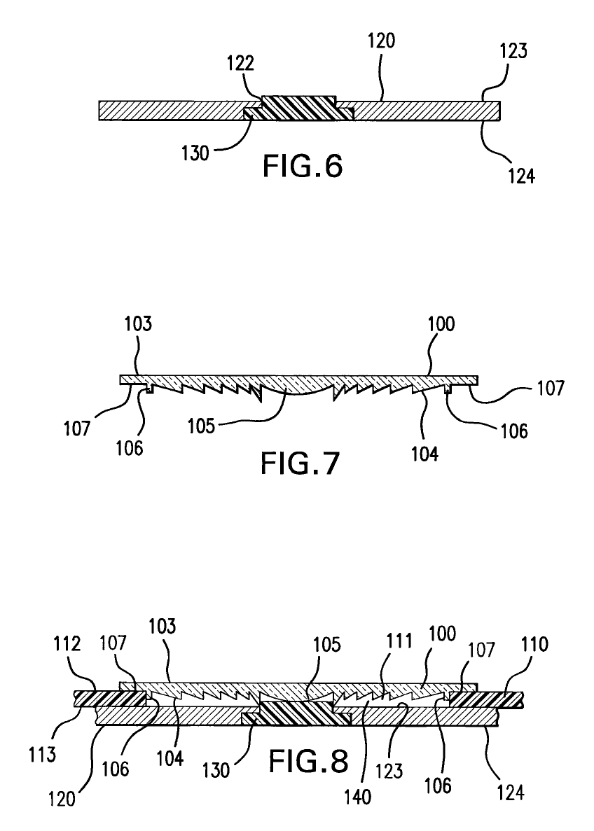

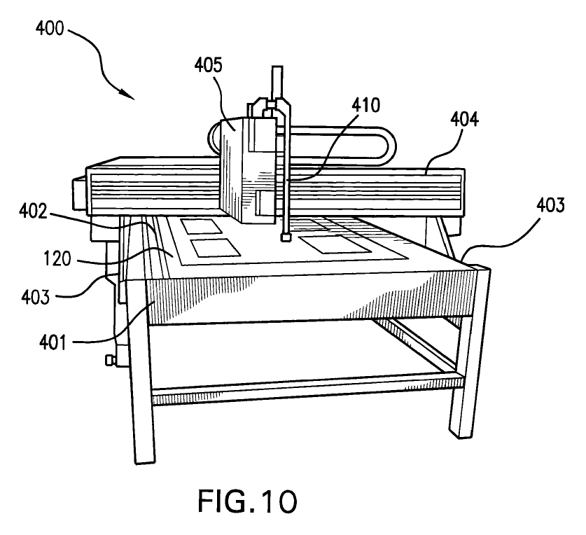

Methods of forming the integral lens sheet 200 provide for accurate positioning of the lenses 100 on the parquet member 110. Initially, the alignment fixture 120 is positioned on a laser welding station 400 as illustrated in FIG. 10. Examples of laser welding systems are available from Shop Sabre of Elko Minnesota, U.S.A., Leister Technologies LLC of Itasca, Ill., U.S.A., and Leister Process Technologies of Samen, Switzerland. The laser welding system 400 includes a bench 401 with a support surface 402 for positioning the alignment fixture 120 with the second surface 124 against the support surface 402 and the first surface 123 facing upward. The alignment members 130 may be attached to the alignment fixture 120 before or after the alignment fixture 120 is positioned on the support surface 402. Attachment of the alignment members 130 includes inserting the neck 133 of the alignment member 130 into the desired aperture 122 in the alignment fixture 120. The length of the neck 133 provides for neck 133 to extend through the aperture 122 and outward beyond the first surface 123 of the alignment member 120. The contact member 134 within the neck 133 may also be positioned above the first surface 123. The sectional shape of the neck 133 may be the same as the aperture 122 thus the outer surface of the neck 133 contacts against the aperture 122 to provide precise positioning. A first surface of the flange 132 contacts against the surface of the aperture 122b to control a depth that the alignment member 130 is positioned into the aperture 122 and also an x-y position of the corresponding lens 100. In one embodiment as illustrated in FIG. 6, the second surface of the alignment member 130 maybe flush with the second surface 124 of the alignment fixture 120 when the alignment member 130 is fully mounted. The alignment member 130 may then be attached by inserting fasteners 190 through the receptacles 126 in the alignment fixture 120 and into the receptacles 135 in the flange 132 of the alignment member 130. An adhesive may be used in combination with the fasteners 190, or in place of the fasteners 190 to attach the alignment member 130.

Once the alignment members 130 are attached to the alignment fixture 120, the parquet member 110 is positioned on the first surface 123 of the alignment fixture 120. Pins may extend outward from the first surface 123 of the alignment fixture 120 to fit in corresponding receptacles in the second surface 113 of the parquet member 110 to align the two members. The positioning may also include aligning the peripheral edges of the parquet member 110 with peripheral edges of the alignment fixture 120. The bench 401 may also provide for positioning the parquet member 110. The bench 401 may include alignment surfaces against which the parquet member 110 abuts for alignment relative to the alignment fixture 120. When accurately positioned, the alignment sections 121 of the alignment fixture 120 are positioned within the apertures 111 of the parquet member 110. When aligned, the entirety or a portion of the alignment sections 121 may be exposed within the apertures 111.

The pins that extend from the second surface 123 of the alignment fixture into the corresponding receptacle in the parquet member 110 maintain the accurate alignment of the parquet member 110 relative to the alignment fixture 120. Additionally, clamps or other like devices may maintain the position of the parquet member 110. These devices provide for maintaining the position and may be detached once the integral lens sheet 200 is complete.

Once the parquet member 110 is positioned on the first surface 123 of the alignment fixture 120, the lenses 100 are aligned and attached to the parquet member 110. Each individual lens 100 is aligned with a corresponding aperture 111 in the parquet member 110. The positioning of each lens 100 includes placing the extensions 106 against the edges of the aperture 122 as illustrated in FIG. 8. This positioning also locates the central section 105 of the lens 100 against the alignment member 130 that extends through the aperture 122. This contact prevents damage from occurring to the central section 105. The section of the alignment member 130 that contacts the central section 105, either the neck 133 or the contact member 134 within the neck 133, may be constructed from a softer material than the lens 100. Examples of the material include but are not limited to Delrin, acetylcopolymer, and plastic.

The lens 100 is also larger than the aperture 111 with the peripheral section 107 of the lens overlapping the parquet member 110 as illustrated in FIG. 8. The lens 100 overlap extends around the aperture 111. The peripheral section 107 of the lens 100 may also be positioned against an o-ring that is mounted in the groove 125.

As illustrated in FIG. 8, a gap 140 is formed between the lens 100 and the alignment fixture 120. The gap 140 is formed because of the relative thicknesses of the parquet member 110 and the lens 100. The vacuum aperture 127 extends into the gap 140 and provides for a vacuum to be applied to create a force that maintains the position of the lens 100 relative to the parquet member 110. The strength of the vacuum may vary, provided it is adequate to maintain the position of the lens 100 on the parquet member 110. The strength of the vacuum may be adjusted to maintain the lens 100 against the parquet member 110, but limited from reaching an amount that the lens 100 and/or the parquet member 110 may be damaged.

Once positioned and held by the vacuum, the lens 100 is attached to the parquet member 110. One method of attachment is laser welding using the laser welding station 400. A laser 410 is mounted on a shuttle 405 that moves lateral along a track 404. The laser 410 is further moved longitudinally as the track 404 slides along rails 403 on the bench 401. The laser 410 is moved around each of the lenses 100 with a laser beam emitted from the laser 410 penetrating through the peripheral section 107 of the lens 100 that overlaps the parquet member 110 and into the underlying parquet member 110. The peripheral section 107 is light transmissive with the laser beam penetrating through to the underlying first surface 112 of the parquet member 110. The section of the first surface 112 that contacts the peripheral section 107 is light absorptive such that the parquet member 110 absorbs the laser beam thereby producing heat. The vacuum being applied through the vacuum aperture 127 presses the peripheral section 107 against the first surface 112 and causes the heat generated in the parquet member 110 to be conducted to the peripheral section 107 of the lens 100. This conduction causes both the parquet member 110 and peripheral section 107 of the lens 100 to melt thereby creating a weld that permanently attaches the lens 100 to the parquet member 110. The laser 410 and/or shuttle 405 may also contact against the lens 100 and apply additional pressure to maintain the position until the weld solidifies.

The laser beam may be moved around the entire aperture 111 to form a continuous airtight weld. The continuous weld securely attaches the lens 100 to the parquet member 110, and also prevents penetration of moisture and other debris.

After the welding is complete, the welds may be checked by removing the integral lens sheet 200 and placing it on paper towels or the like. Water is applied to the top surface (i.e., against surfaces 112 and 123). Any failure in the welds will result in water leaking through the integral lens sheet 200 and wetting the paper towels. The welds of each integral lens sheet 200 may be checked, or just a limited number of integral lens sheets 200 may be checked.

The method of constructing the integral lens sheet 200 may include separately positioning and attaching one lens 100 at a time on the parquet member 110. Other embodiments may include positioning and attaching multiple lenses 100 concurrently on the parquet member 110.

Once each of the lenses 100 is attached to the parquet member 110, the integral lens sheet 200 may be removed from the alignment fixture 120. The integral lens sheet 200 may then be mounted on the frame 301 as part of the overall photovoltaic solar cell subassembly as illustrated in FIG. 9.

The method described above included the alignment members 130 being attached to the alignment fixture 120 after the alignment fixture 120 is mounted on the bench 401. Alternatively, the alignment members 130 may be attached to the alignment fixture 120 prior to mounting the alignment fixture 120 on the bench 401.

In some embodiments, a vacuum is not applied to maintain the position of the lens 100 on the parquet member 110. The lens 100 is adequately maintained on the parquet member 100 to allow for attachment without the need for applying a vacuum.

The embodiments of the integral lens sheet 200 described above each include numerous lenses 100 that are attached to the parquet member 110. In another embodiment, the integral lens sheet 200 includes a single lens 100 attached to the parquet member 110.

Laser welding is one method of attaching the lenses 100 to the parquet member 110. Other methods may include but are not limited to heat welding, ultrasonic welding, and adhesives.

The lens 100 may include one or more extensions 106 on the second surface 104. Lens 100 may also be formed without the extensions 106 with the lens 100 simply positioned in contact with the first surface 112 of the parquet member 110.

Spatially relative terms such as “under”, “below”, “lower”, “over”, “upper”, and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The present invention may be carried out in other specific ways than those herein set forth without departing from the scope and essential characteristics of the invention. The present embodiments are, therefore, to be considered in all respects as illustrative and not restrictive, and all changes coming within the meaning and equivalency range of the appended claims are intended to be embraced therein.

What is claimed is:

1. A method of forming an integral lens sheet from a parquet member and individual lenses for a photovoltaic solar cell subassembly, the method comprising:
positioning individual lenses over respective apertures formed in a parquet member with peripheral sections of the individual lenses overlapping the parquet member; and
laser welding the individual lenses to the parquet member by directing a laser beam through the peripheral sections of the individual lenses and onto the parquet member and forming a laser weld between the parquet member and undersides of the individual lenses.

2. The method of claim 1, further comprising positioning the peripheral sections of the individual lenses over darkened, laser-absorbing sections on the parquet member and directing the laser beam through the peripheral sections and onto the darkened, laser-absorbing sections.

3. The method of claim 1, further comprising applying a vacuum to the individual lenses to maintain the individual lenses against the parquet member prior to laser welding the individual lenses to the parquet member.

4. The method of claim 1, further comprising laser welding around the entirety of each of the individual lenses and forming a continuous seam between each of the individual lenses and the parquet member.

5. The method of claim 1, wherein the step of laser welding the individual lenses to the parquet member includes welding each of the individual lenses one at a time to the parquet member.

6. The method of claim 1, further comprising aligning extensions on a second surface of each of the individual lenses with the respective apertures in the parquet member.

7. A method of forming an integral lens sheet from a support member and an individual lens for a photovoltaic solar cell subassembly, the method comprising:
positioning a lens over an aperture formed in the support member;
overlapping a light-transmissive peripheral section of the lens over a light-absorptive border region of the support member that surrounds the aperture;
directing a laser beam through the light-transmissive peripheral section of the lens and onto the light-absorptive border region that surrounds the aperture; and
forming a laser weld between a second surface of the lens and the first surface of the support member, the laser weld extending around the aperture.

8. The method of claim 7, further comprising laser welding additional lenses onto the support member.

9. The method of claim 7, further comprising vacuuming the lens against the parquet member and maintaining the second surface of the lens in contact against the parquet member while forming the laser weld.

10. The method of claim 7, forming the laser weld between the lens and the parquet member to be airtight.

11. A method of forming an integral lens sheet from a support member and individual lenses for a photovoltaic solar cell subassembly, the method comprising:
positioning a separate Fresnel lens over different apertures formed in the support member;
overlapping light-transmissive peripheral sections of the Fresnel lenses over light-absorptive border regions of the support member that surround each of the apertures;
directing a laser beam around each of the apertures and through the light-transmissive peripheral sections of the Fresnel lenses and onto the light-absorptive border regions that surround the apertures; and
forming airtight laser welds between each of the Fresnel lenses and the support member.

12. The method of claim 11, further comprising supporting a central section of each of the Fresnel lenses prior to forming the airtight laser welds.

13. The method of claim 11, wherein each of the Fresnel lenses includes substantially identical shapes and sizes.

14. The method of claim 11, wherein each of the apertures includes substantially identical shapes and sizes.

15. The method of claim 11, further comprising applying a force to each of the Fresnel lenses to maintain the position on the support member prior to forming the airtight laser welds.

16. A method of forming an integral lens sheet from a sheet and an individual lens for a photovoltaic solar cell subassembly, the method comprising:
attaching a contact member to an alignment fixture with the contact member extending outward beyond a top surface of the alignment fixture;
positioning a bottom surface of a sheet onto the top surface of the alignment fixture with a lens aperture in the sheet positioned over the contact member in the alignment fixture;
positioning a bottom surface of a lens on a top surface of the sheet with a central section of the lens positioned over the lens aperture and in contact against the contact member;
overlapping a peripheral section of the lens with a contact section on the top surface of the sheet that surrounds the lens aperture; and
welding the peripheral section of the lens to the contact section of the sheet and forming an airtight weld that extends around the aperture.

17. The method of claim 16, further comprising applying a vacuum through a vacuum aperture in the alignment fixture to maintain the lens positioned over the lens aperture and in contact with the top surface of the sheet during the welding.

18. The method of claim 16, further comprising spacing a portion of the lens between the central section and the peripheral section from the alignment fixture and the parquet member prior to welding the peripheral section to the contact section.

19. The method of claim 16, wherein the step of overlapping the peripheral section of the lens with the contact section on the top surface of the sheet that surrounds the lens aperture comprises positioning a light-transmissive section of the peripheral section over a light-absorbing section of the contact section.

20. The method of claim 16, wherein the step of welding the peripheral section of the lens to the contact section of the sheet and forming an airtight weld that extends around the aperture includes directing a laser beam through the peripheral section of the lens that is light-transmissive and onto the contact section that is light-absorptive.

21. The method of claim 16, further comprising welding at least one additional lenses to the sheet.

22. A method of forming an integral lens sheet from a base member and individual lenses for a photovoltaic solar cell subassembly, the method comprising:
attaching contact members within alignment apertures of an alignment fixture, the contact members extending outward beyond a first surface of the alignment fixture;
positioning a second surface of the base member onto the first surface of the alignment fixture with lens apertures in the base member aligning with the alignment apertures in the alignment fixture;
positioning each of the individual lenses on a first surface of the base member with a central section of each of the individual lenses contacting against one of the contact members and a peripheral section of each of the lenses overlapping with the base member in regions that surround the lens apertures;
applying a vacuum through vacuum apertures in the alignment fixture to maintain the lenses positioned over the lens aperture and in contact with the first surface of the base member; and
welding the peripheral sections of the lenses to the regions of the base member that surround the apertures.

23. The method of claim 22, wherein the step of welding the peripheral sections of the lenses to the regions of the base member that surround the apertures includes directing a laser beam through the peripheral sections.
